(19) United States
(12) Patent Application Publication
(10) Pub. No.: US 2007/0040165 A1
(43) Pub. Date: Feb. 22, 2007

(54) Method of fabricating organic FETs

(76) Inventors: Klaus Dimmler, Colorado Springs, CO (US); Robert R. Rotzoll, Chipita Park, CO (US)

Correspondence Address: HOGAN & HARTSON LLP, ONE TABOR CENTER, SUITE 1500, 1200 SEVENTEENTH ST, DENVER, CO, 80202, US

(21) Appl. No.: 11/204,725

(22) Filed: Aug. 16, 2005

(51) Int. Cl. H01L 51/00; H01L 51/40

(52) U.S. Cl. 257/40; 257/66; 438/99; 438/151

(57) ABSTRACT

At least two thicknesses of dielectric are formed in the fabrication of organic field effect transistors. One thickness is formed in the active regions of the transistor for adjusting the desired threshold of the device. A second thickness is deposited in the field regions of the transistor to electrically isolate the transistors, and reduces leakage current and capacitance. A third dielectric thickness that is thicker than the first thickness but thinner than the second thickness can be used to define transistors having a second threshold voltage. The multiple dielectric thicknesses can be produced by multiple cell sizes of a gravure roll when using gravure printing, multiple cell sizes in an anolox roll in flexography printing, multiple nozzle size and chamber pressure in inkjet printing, or by printing successive layers of a single thickness of dielectric. The method can be employed in top gate, bottom gate top contact, and in bottom gate bottom contact organic transistor structures.

### BACKGROUND OF THE INVENTION

1. Field of the Invention

The invention relates to organic transistors, and, more particularly, to a method of fabricating organic FETs having at least two thicknesses of dielectric.

2. Description of the Related Art

Organic field-effect transistors (oFETs) have been proposed for a number of applications including displays, electronic barcodes and sensors. Low cost processes, large-area circuits and the chemically active nature of organic materials are the chief driving forces making oFETs important in various applications. Many of these objectives depend on a method of fabrication utilizing printing techniques such as flexography and gravure printing.

Organic MOS transistors are similar to silicon metal-oxide-semiconductor transistors in operation. The major difference in construction is that the organic MOS transistor utilizes a thin layer of a semiconducting organic polymer film to act as the semiconductor of the device, as opposed to a silicon layer as used in the more typical in-organic silicon MOS device.

Referring now to FIG. 1, a cross-sectional diagram of a top-gate bottom contact organic MOS transistor 100 is shown. A metallic region 122 is deposited on an insulating substrate 112 forming the gate 122 of the organic MOS device 100. A thin dielectric region 120 is placed on top of gate region 122 to electrically isolate it from other layers and to act as the MOS gate insulator. Metallic conductors 118 and 116 are formed on the dielectric region 120 above the gate region 122 such that there is a gap 124 between conductors 116 and 118 overlapping gate metal 122. The gap 124 is known as the channel region of transitory 100. A thin film of organic semiconducting material 114 is deposited on dielectric region 120 and over at least a portion of metallic conductors 116 and 118. A voltage applied between the gate 122 and the source 118 modifies the resistance of the organic semiconductor film 114 in gap region 124 in the vicinity of the interface between semiconductor region 124 and dielectric 120. This is defined as the “field effect”. When another voltage is applied between the source 118 and the drain 116, a current flows between the drain and source with a value dependent on both the gate-to-source and the drain-to-source voltages.

In order to provide a complete circuit, it is necessary to establish an electrical connection between the gate metal and the source/drain metal. This is achieved by patterning an opening through the dielectric before the source/drain metal is deposited. This results in an opening connecting a source/drain metal region with a gate metal region.

The organic transistor 200 can also be constructed as a top-gate top contact structure as shown in FIG. 2. Conductor layer 222 is deposited and patterned on substrate 212. A dielectric layer 220 is deposited on conductor layer 222. A thin film of semiconductor material 214 is deposited on top of dielectric layer 220. A conductive film is deposited and patterned on top of organic semiconductor 214 to form conductive source and drain regions 216 and 218, such that there is a gap 224 that overlaps the underlying gate metal layer 224. The gap 224 is known as the channel region of transistor 200. Through a field effect, a voltage is applied between gate conductor 222 and source 218 modifies the resistance of the organic semiconductor 214 in the gap region 224 in the vicinity of the interface between the semiconductor region 224 and the dielectric 220. When another voltage is applied between source 218 and drain 216, a current flows between the drain and the source with a value dependence on both the gate-to-source and the drain-to-source voltages.

Again, in a complete process, a connection between the gate metal and the source/drain metal is achieved by patterning an opening through the dielectric and organic semiconductor before the source/drain is deposited. This results in an opening connecting a source/drain metal region with a gate metal region.

Organic transistor 300 can also be constructed as a top gate structure as shown in FIG. 3. A conductive film is deposited and patterned on an insulating substrate 312 to form conductive regions 318 and 316. One of these conductive regions is known as the source 318, and the other as the drain 316. The gap 324 between them is known as the channel region of transistor 300. A thin organic semiconductor layer is deposited on top of these conductive regions such that the entire gap 324 and at least a portion of conductive regions source 318 and drain 316 are covered. A dielectric layer 320 is deposited on top of semiconductor layer 320. A conductive layer 322 is deposited and patterned such that at the underlying gap 324 and at least a portion of the source 316 and the drain 316 are covered. A field effect causes the resistance of the organic semiconductor 320 inside the gap 324 in the vicinity of the interface between the semiconductor 320 and the dielectric 320 to decrease as a voltage is applied between the gate 320 and the source 318. When another voltage is applied between the source 318 and the drain 316, current flows between the source 318 and the drain 316 the value of which depends on the voltage between gate 300 and the source 318.

Similarly, in order to produce a complete circuit, it is necessary to establish an electrical connection between the gate metal and the source/drain metal. This is achieved by patterning an opening through the dielectric before the gate metal is deposited. This results in an opening connecting a source/drain metal region with a gate metal region.

In all of these structures, all layers may be patterned as long as the gate conductor overlaps the channel region gap and at least a portion of the source and drain, and organic semiconductor and dielectric are placed so that the gate conductor and the source/drain conductor are electrically isolated.

The organic semiconductor materials are often classified as polymeric, low molecular weight, or hybrid. Pentacene, hexithiphene, TPD, and PBD are examples of low weight molecules. Polythiophene, parathenylene vinylene, and polyphenylene ethylene are examples of polymeric semiconductors. Polyvinyl carbazole is an example of a hybrid matrial. These materials are not classified as insulators or conductors. Organic semiconductors behave in a manner that can be described in terms analogous to the band theory in inorganic semiconductors. However, the actual mechanics giving rise to charge carriers in organic semiconductors are substantially different from inorganic semiconductors. In inorganic semiconductors, such as silicon, carriers are generated by introducing atoms of different valencies into a host crystal lattice, the quantity of which is described by the number of carriers that are injected into the conduction band, and the motion of which can be described by a wave vector k. In organic semiconductors, carriers are generated in certain materials by the hybridization of carbon molecules in which weakly bonded electrons, called π electrons, becomes delocalized and travel relatively far distances from the atom which originally gave rise to that electron. This effect is particularly noted in materials comprising of conjugated molecules or benzene ring structures. Because of the delocalization, these π electrons can be loosely described as being in a conduction band. This mechanism gives rise to a low charge mobility, a measure describing the speed with which these carriers can move through the semiconductor, resulting in dramatically lower current characteristics of organic semiconductors in comparison to inorganic semiconductors.

Besides a lower mobility, the chemistry of carrier generation gives rise to another key difference between the operation of an organic MOS transistor and inorganic semiconductor. In the typical operation of an inorganic semiconductor, the resistance of the channel region is modified by an “inversion layer” consisting of the charge carriers made up of the type of charge that exists as a minority in the semiconductor. The silicon bulk is doped with the opposite type of carrier as compared to that used for conduction. For example, a p-type inorganic semiconductor built with an n-type semiconductor, but used p-type carriers, also called holes, to conduct current between the source and drain. In the typical operation of an organic semiconductor, however, the resistance of the channel region is modified by an “accumulation layer” consisting of charge carriers made up of the type of charge that exists as a majority in the semiconductor. For example, a PMOS organic transistor uses a P-type semiconductor and p-carriers, or holes, to generate the current in typical operation.

In the processing of inorganic semiconductors such as silicon, transistors are isolated from each other by means of a thick dielectric between transistors, often referred to as field oxide. One common method of forming this field oxide is through a process called LOCOS, wherein the channel, source and drain regions of the transistors are masked with silicon nitride and then expose the silicon to oxygen or steam at high temperature. The exposed silicon oxidize and forms silicon dioxide while silicon protected by the silicon nitride mask does not. Another method of forming this oxide, called a trench isolation process, involves etching into the silicon in the field regions, depositing a dielectric, and planarizing the surface. Besides providing isolations, field oxide also reducing the parasitic capacitance that arises when a metal interconnect underneath the field oxide (a first layer of metal) overlaps a metal interconnect above the field oxide (a second layer of metal). Further, the leakage through the dielectric from the first layer of metal and the second layer of metal is reduced. The thicker the field oxide, the more the parasitic capacitance and the leakage through the dielectric is desirably reduced.

In organic semiconductor processing, isolation between transistors is typically provided by not depositing semiconductor in the field regions. In such processing, the dielectric thickness is chosen to optimize the threshold of the transistors, and is deposited in both active and field regions. Since there is no semiconductor in the field regions, carriers do not form carrier channels, thereby providing the desired isolation. However, this solution results in high capacitance between the first and second layers of metal, as well as an undesirable high leakage through the dielectric.

Another limitation with this prior art is that when using some print techniques, the total lack of a semiconductor deposition in the field regions cannot be guaranteed. In gravure printing, for example, the non-image areas on the print roller are deliberately designed to pick up a small amount of ink in order to produce lubrication to the doctor blade which scrapes off the ink in the non-image areas. Cross-hatches are engraved in the non-image areas so that the doctor blade which removes excess ink does not wear or chatter. While this small amount of ink is inconsequential when gravure is used for visual print, the electrical properties resulting from these small amounts of ink can be highly detrimental. In this case, a thin coating of semiconductor ink may deposit on the substrate may give rise to charge carriers in the field region of the transistor causing undesired cross talk between individual transistors.

What is desired, therefore, is a practical method of isolating transistors in an organic integrated process.

### SUMMARY OF THE INVENTION

According to an embodiment of the present invention, at least two thicknesses of dielectric are formed in the fabrication of organic field effect transistors. One thickness is formed in the active regions of the transistor, thereby providing a means for adjusting the desired threshold of the device. A second thickness is deposited in the field regions of the transistor, thereby providing a means to electrically isolate the transistors. In addition, this second thickness of dielectric serves to reduce leakage current and reduce the capacitance between a first layer of metal underneath the dielectric and a second layer of metal above the dielectric. In another embodiment of this invention, a third thickness that is thicker than the first thickness but thinner than the second thickness can be used to define transistors having a second threshold voltage. These multiple thicknesses of dielectric can be produced by multiple cell sizes of the gravure roll when using gravure printing, multiple cell sizes in the anolox roll in flexography printing, multiple nozzle size and chamber pressure in inkjet printing, or by printing successive layers of a single thickness of dielectric. This method can be employed in a top gate, bottom gate top contact, and in bottom gate bottom contact structures.

### BRIEF DESCRIPTION OF THE DRAWINGS

The present invention is illustrated by way of example and not by limitation in the accompanying figures in which like reference numerals indicate similar elements and in which:

FIGS. 1-3 are cross-sectional views of an inorganic MOS transistor including an insulating substrate, organic polymer film, dielectric layer, and conductive gate according to the prior art;

FIG. 4 illustrates an embodiment of the disclosed invention as applied to a top gate organic FET structure;

FIG. 5 illustrates an embodiment of the disclosed invention as applied to multiple threshold transistors having different dielectric thicknesses;

FIG. 6 illustrates an embodiment of the disclosed invention as applied to a gravure roll surface having multiple depths of cells in the image areas;

FIG. 7 illustrates an embodiment of the disclosed invention as applied to a gravure roll surface having multiple depths of cells in the image areas wherein the cells in the image area are joined with a surface lower than the surface of the roll;

FIG. 8 illustrates an embodiment of the disclosed invention as applied to a gravure roll surface wherein the image areas are defined with a single cavity;

FIG. 9 illustrates an embodiment of the disclosed invention as applied to an anolox roll having different cell depths to produce varying amounts of ink on a flexographic print plate;

FIG. 10 illustrates an embodiment of the disclosed invention as applied to an inkjet nozzle wherein different drop sizes are dropped on the surface through inkjet control parameters, thereby creating a varying thickness of dielectric layer;

FIG. 11 illustrates an embodiment of the disclosed invention as applied to successive depositions of dielectric, thereby forming a varying total thickness of dielectric on the substrate;

FIG. 12 illustrates an embodiment of the disclosed invention as applied to a bottom gate top contact organic FET structure; and

FIG. 13 illustrates an embodiment of the disclosed invention as applied to a bottom gate bottom contact organic FET structure.

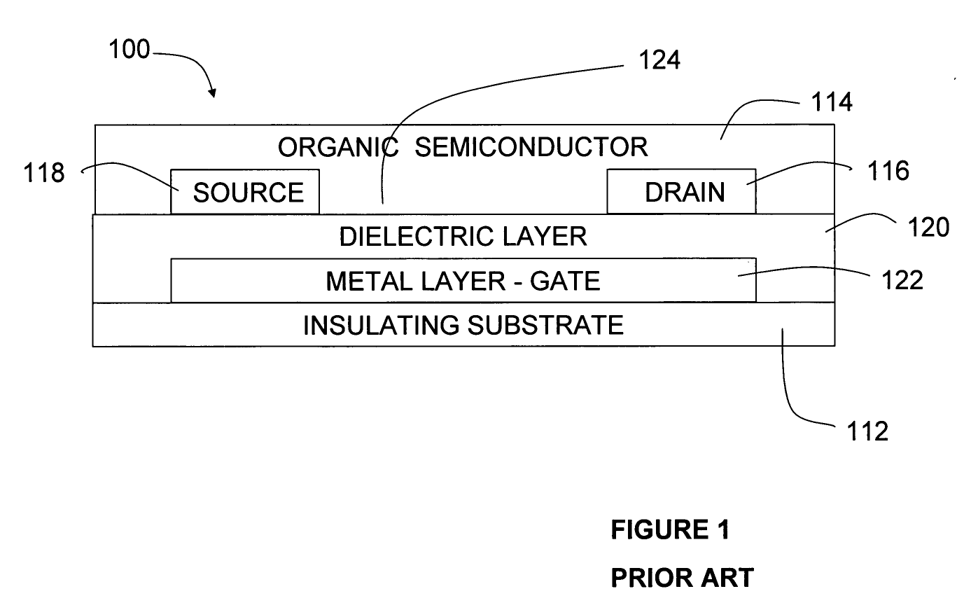

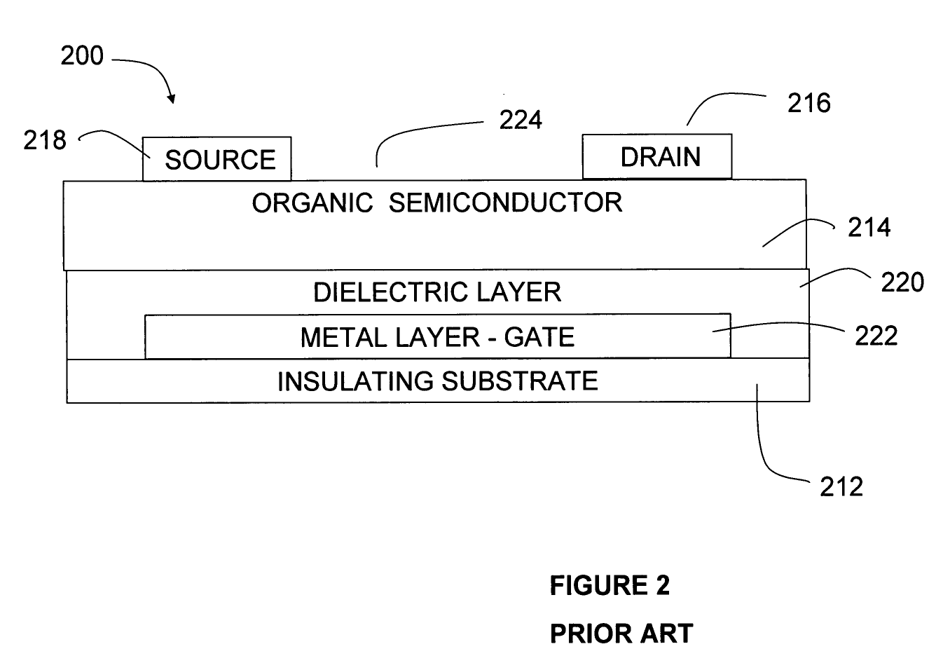

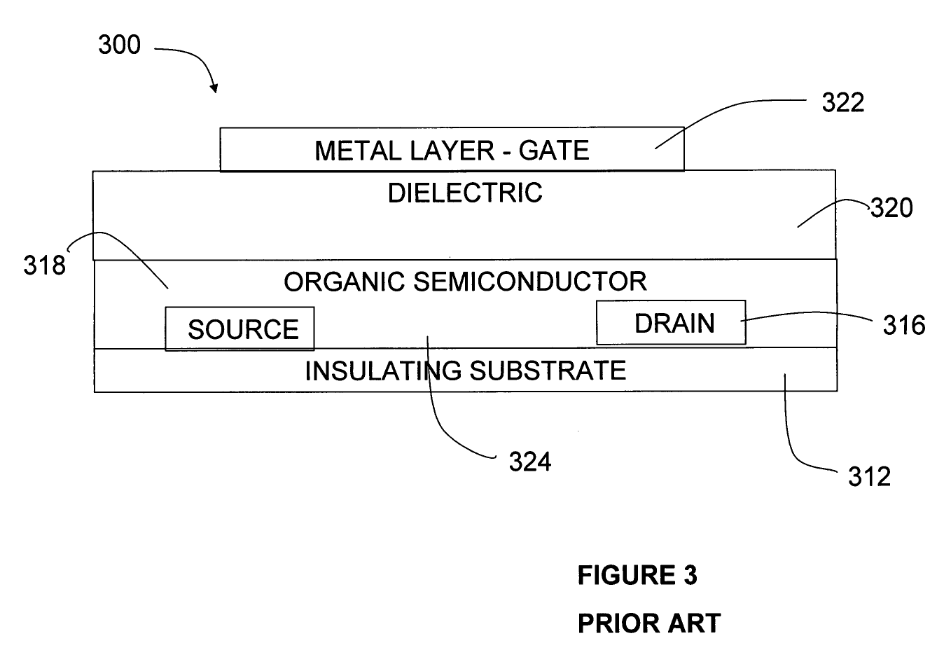

### DETAILED DESCRIPTION

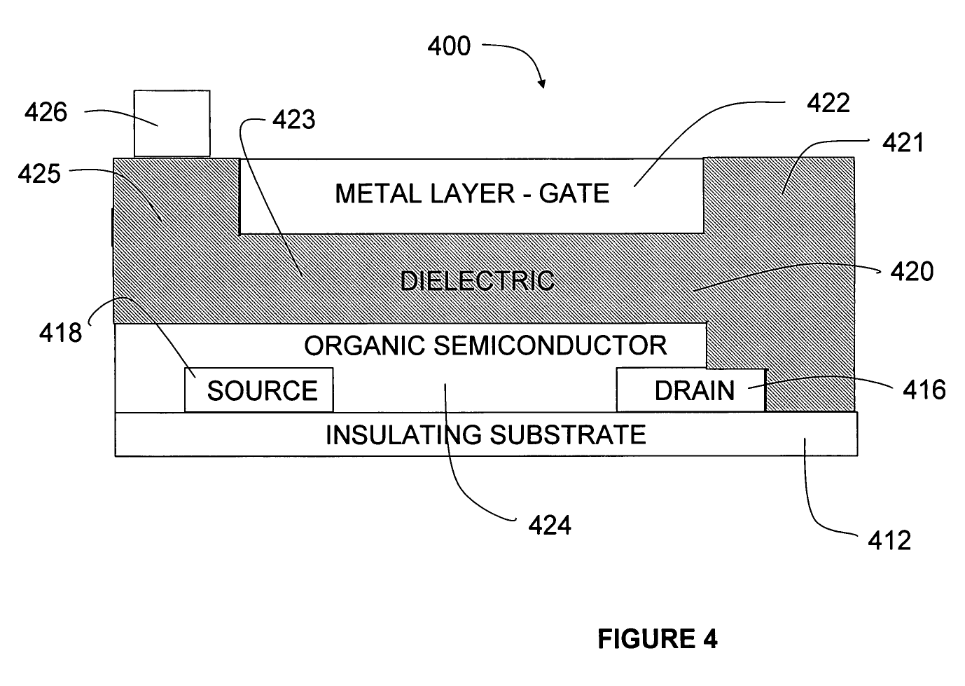

Referring now to FIG. 4, one embodiment of this invention to the top gate structure is described. The process of fabricating an organic FET begins with techniques known in the prior art. A source 418 and drain electrode 416 are deposited on an insulating substrate 412. The insulating substrate includes glass, silicon with silicon dioxide, or flexible substrate such as polyesters, polycarbonates, polyolefins, polyimides, and PEN (polyethylene naphthalate) PET, PETG, polycarbonate, or Kapton. The source 418 and drain 416 electrodes are formed by a patterned conductor. Materials for the patterned conductor include gold, silver, nickel, copper, or conductive polymers such as PEDOT and conductive polythiophene. Deposition methods include evaporation, spinning, or printing. Patterning methods include substantive techniques such as laser ablation, chemical etching, dry etching, and additive techniques including printing, ink jetting, and surface modification.

An organic semiconductor 424 is then deposited on the patterned source/drain layer, materials including low molecular weight materials such as hexithiophene, pentacene, perlylene, TPD, or polymeric organic semiconductors such as polythiophene, poly(para-pjenylene vinylene) PPV, MEH-PPV or Cyano-PPV, or hybrid materials such as poly(vinyl carbazole) PVK.

In the prior art, a single thickness of dielectric material is deposited on the organic semiconductor 424. In this system, when a metal interconnect connects two transistors, charge carriers can be generated in the semiconductor underneath that interconnect. These carriers can then generate an undesirable leakage current between the two transistors. In one embodiment of the invention disclosed herein, the dielectric 420 is deposited having at least two thicknesses. A thin dielectric layer 423 is deposited in the active region of the transistor, defined as the area between the source and drain and at least part of the source and drain. A thick dielectric 421, 425 is deposited in all regions that are not active area, called the field region. This thicker dielectric is made sufficiently thick so that carriers are not generated below an interconnect metal when the maximum voltage is applied to that interconnect metal, thereby greatly reducing the leakage current between transistors. Therefore, this field dielectric 421 and 425 serves to electrically isolate the active regions of the transistor and decrease capacitance between the first layer of metal and the second layer of metal. The field dielectric can be deposited over a portion of the source 418 or drain 416, or directly on the substrate 412, as shown in FIG. 4 in dielectric section 420. Alternatively, the field oxide can be deposited on organic semiconductor 424, as shown in FIG. 4 in dielectric section 425.

The vertical dimension of the thin dielectric in the active regions defines the threshold voltage of the transistor, which is defined as the voltage between the gate and the source at which the transistor begins to conduct active current.

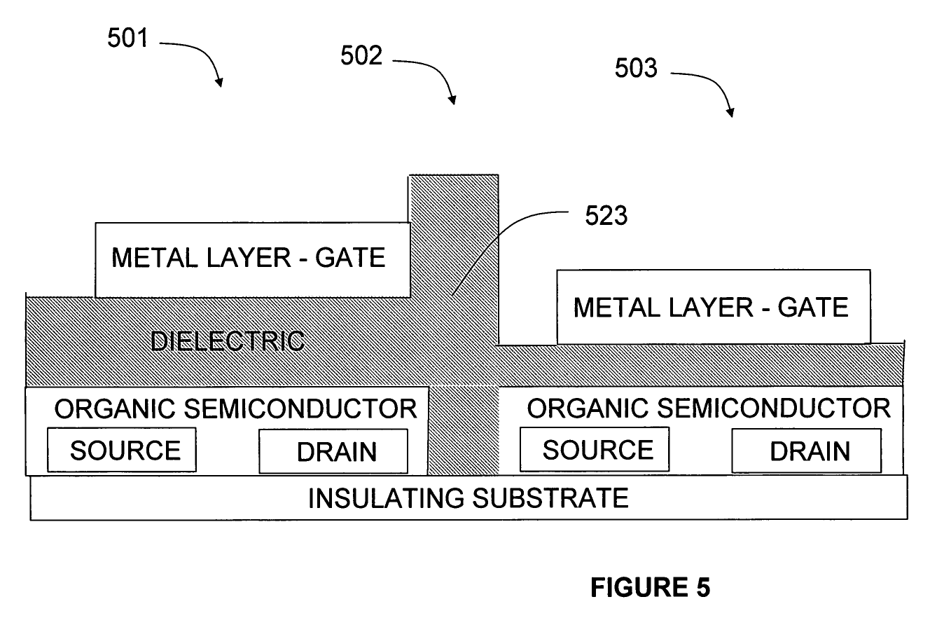

FIG. 5 illustrates another embodiment, in which transistor 501 has a thicker dielectric 521 than transistor 503, separated by a region 502 having an even thicker dielectric serving to isolate the two transistors 501 and 503. A thicker dielectric in a transistor results in a higher threshold voltage than that of a thinner dielectric. Therefore, such processing advantageously allows the use of transistors having different thresholds in the design of circuitry.

This dielectric is preferably a material that is printable, such materials including inorganic precursors such as spin-on-glass or polymer-based dielectric such as cross-linked polyvinylphenol (PVP), polypropylene, CYTOP, polyvinylalcohol, ployisobutylene, PMMA, polyethylene terephthalate (PET), poply-p-xylylene, and CYMM. Patterning can be achieved by gravure printing, flexographic printing, or inkjet printing. Variable thickness can be achieved in a single print process in each of these print methods.

In gravure printing, the thickness of the ink deposited depends in great part on the cell size of the roller. The image areas of a gravure roller consist of small indentations in the roller called cells, each of which are designed to pick up a certain amount of ink. The roller is then pressed against the substrate, causing the ink to transfer to the substrate. In a special form of gravure printing, called Electrical Static Assist Printing or ESA gravure printing, an electrical field between the roller and the other side of the substrate is utilized to facilitate the emptying all of the contents in each cell onto the substrate. The ink then flows on the substrate to form a continuous film. The thickness of the dielectric deposits in various image areas is controlled by forming deeper cells in areas for thick dielectric deposits and shallower cells in areas for thinner dielectric deposits.

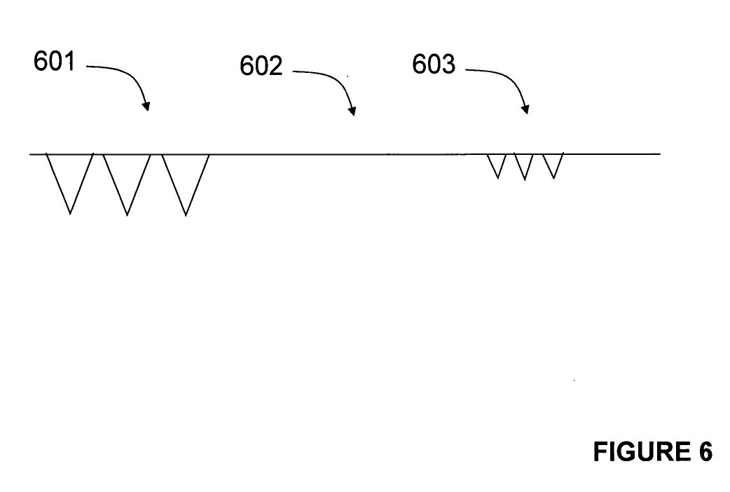

FIG. 6 illustrates the principle described above. Region 601 is an image area with relatively deep cells compared to image area 603, separated by a non-image region 602. Therefore, more ink is transferred to the substrate corresponding to region 601 than on region 603, causing the dielectric deposited to be thicker in region 601. Uniform image areas are formed when the ink deposited from the cells flows together, thereby connecting the cells to form one uniform image area.

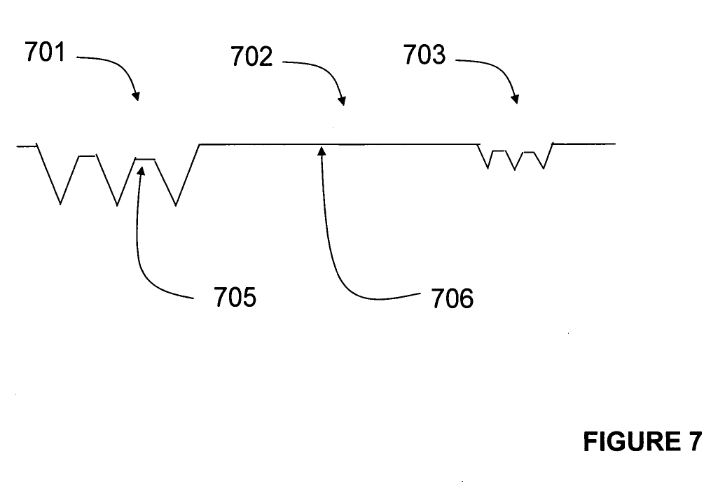

FIG. 7 illustrates another embodiment in which the cells within the image areas are connected with a surface level 705 that is lower than the surface level of the non-image areas 706, causing the cells in the image areas to merge more easily. A more uniform layer can thereby created with any given ink. Note that the surface level 703 of the smaller cells is also lower than the surface level of non-image area 706.

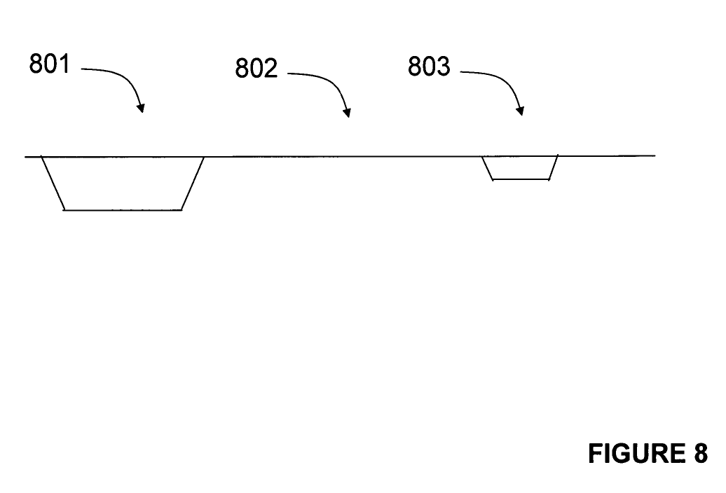

FIG. 8 illustrates another embodiment of this principle in which the image area is one uniform area rather than one consisting of individual cells. Image area region 801 is deeper than image area 803, which is separated by a non-image area 802. This method works provided the image areas are sufficiently small to properly hold the ink within cavity.

In flexography, ink is transferred to a print plate in which the image is raised over non-image areas. The amount of ink that is transferred depends on an anolox roll which has cells for picking up ink. In the prior art, the anolox roll consists of a given density and size of cells, transferring the same amount of ink on all raised surfaces of the print plate. In one embodiment of the invention disclosed in this patent, the anolox roll is patterned with deeper cells in areas for thick dielectric and shallower cells for thinner dielectric, thereby transferring the appropriate amounts of ink to the print plate.

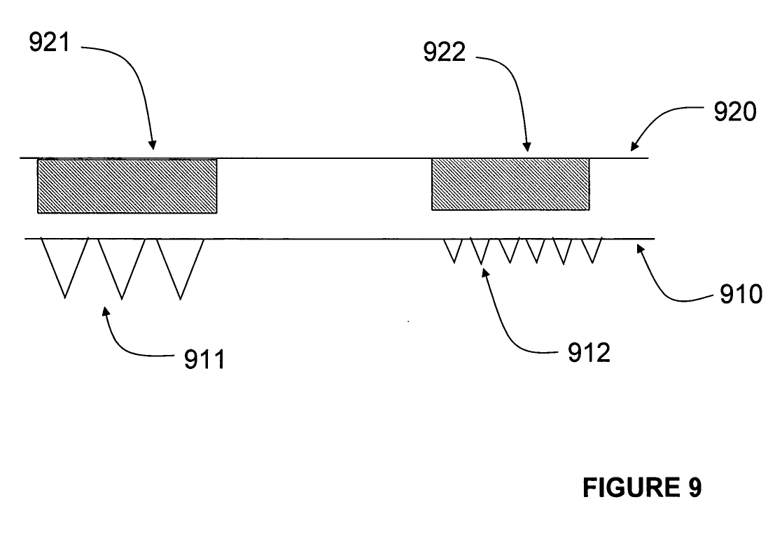

FIG. 9 illustrates the above principle. In FIG. 9, the surface of the anolox roll 910 transfers a different amount of ink on two raise surfaces of print plate 920. The deeper cells 911 hold more ink than cells 912, and therefore transfer more ink to the print plate surface 921 and 922 respectively. The print plate then rotates onto the substrate, transferring these respective amounts of ink on the substrate. This process deposits a thicker layer of dielectric ink on the surface of the substrate corresponding to the cells 911 than 912.

In ink jet technologies, the amount of ink can be controlled by the size of the inkjet nozzle and the pressure applied to the ink within the inkjet head chamber. In areas where a thick dielectric is desired, more ink is deposited than in areas where a thin dielectric is desired.

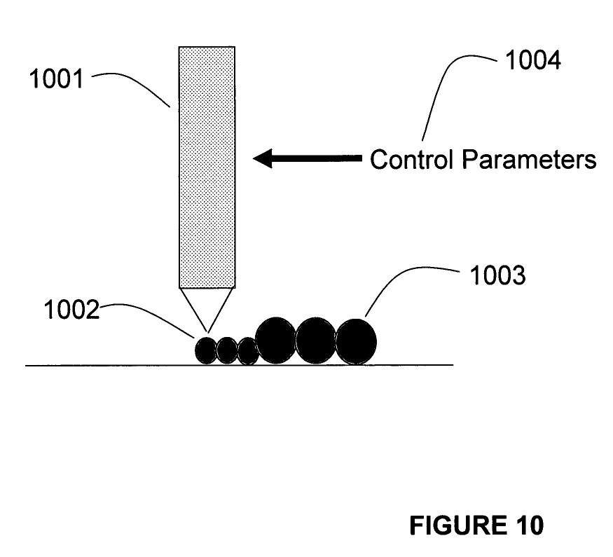

FIG. 10 illustrates the above principle. Inkjet 1001 is controlled by control parameters 1004 to produce a given droplet size. Small droplet sizes 1002 produce a thinner layer of dielectric than the larger droplet sizes 1003.

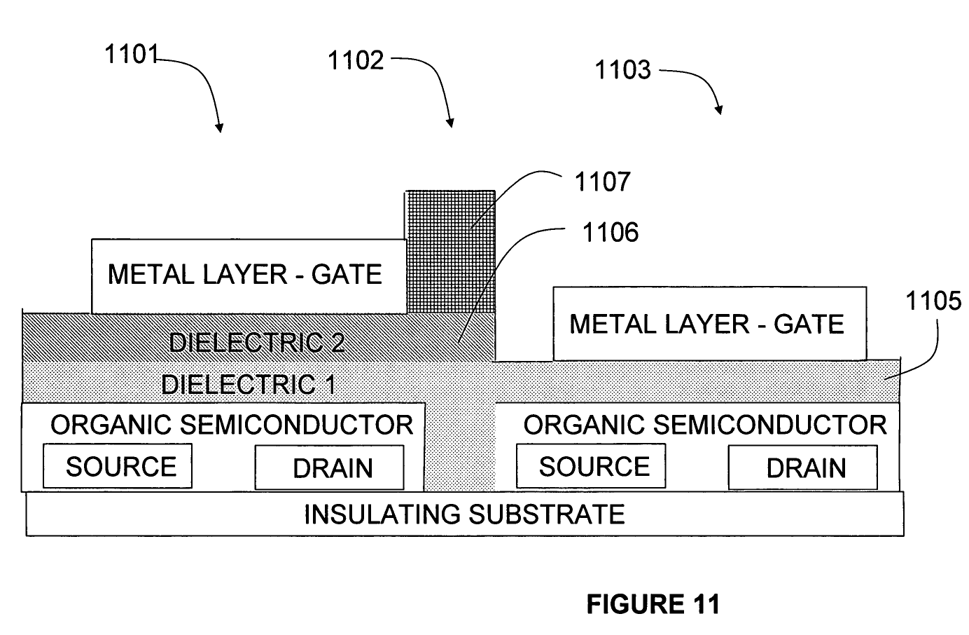

Alternatively, varying thickness of the dielectric can be provided by multiple print steps, as illustrated in FIG. 11. First, a layer of thin dielectric 1105 is deposited in all areas that receive a dielectric layer, thereby creating low threshold transistor 1103. A second layer of dielectric 1106 is the deposited in areas where a thicker dielectric layer is desired, for example to create transistor 1101 having a second threshold voltage level. A third layer of dielectric 1107 could be deposited where an even thicker layer of dielectric is desired, for example in the field regions 1102 of the circuit. It will be appreciated by those skilled in the art that the structure of FIG. 11 can be extended to fabricate multiple transistors such as transistors 1101 and 1103, although only one of each is shown.

Referring again to FIG. 4, a second layer gate metal 422 is now deposited in dielectric 420. The dielectric region 423 over the active area of the transistor has wells on the surface which can be used to better define the placement of the metal ink by allowing the ink to flow into those areas. In addition, the metal 426 can also be patterned over the field oxide as a means of providing interconnect. This metal can also be flowed through holes in dielectric 420, called vias, to connect to the first layer metal beneath the dielectric. Such constructs make electrical connection between the first layer of metal and the second layer of metal, as required by the desired circuit.

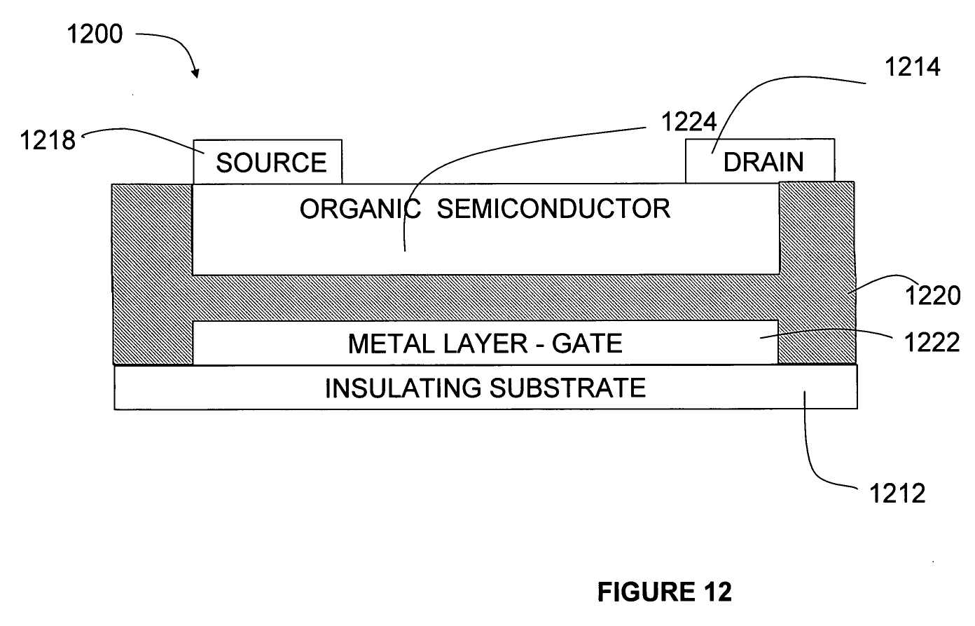

Structure 1200 of FIG. 12 illustrates the application of the principles above to a bottom gate/top contact device. In this structure, the first metal layer 1222 is utilized as the gate of the transistor, and is deposited on insulating substrate 1212. The dielectric 1220 having multiple thicknesses is formed on top of the first metal layer. At least one thicknesses of thin dielectric is deposited in the active regions of the transistors, the active area being defined as the regions consisting at least a portion of the source, at least a portion of the drain, and the space between the source and drain. The field regions have at least a second thickness of dielectric material 1220.

Still referring to FIG. 12, the organic semiconductor 1224 is now deposited. The region formed between the walls of the field oxides serves to guide the organic semiconductor solution. The second metal layer is then formed, patterned to form the source 1218 and the drain 1214. The source and drain can be placed entirely on the organic semiconductor as shown in source 1218, or could be placed in part over the field dielectric, as shown in drain 1214.

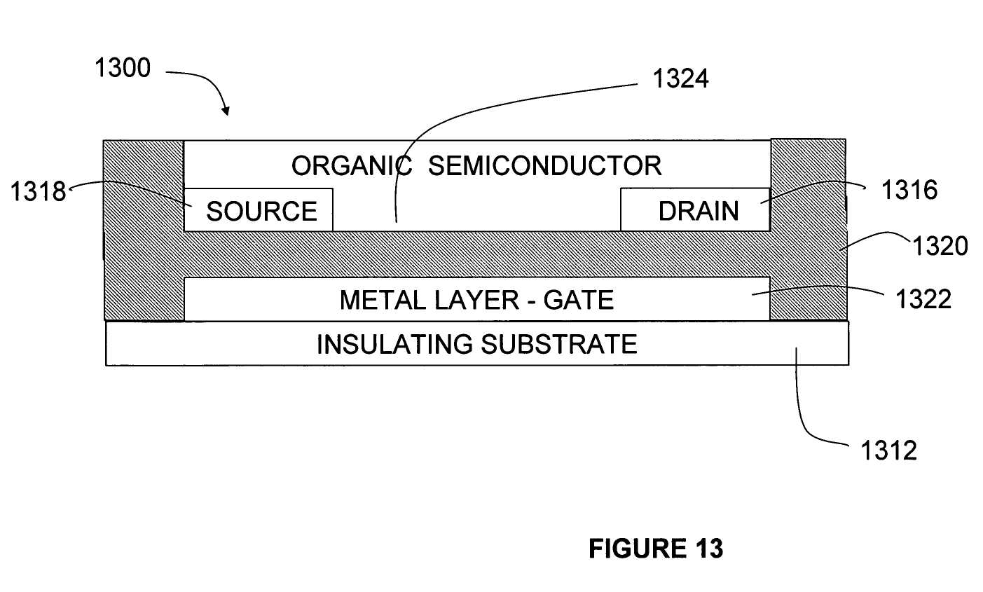

Structure 1300 of FIG. 13 illustrates the application of the principles disclosed herein on a bottom gate/bottom contact device. In this structure, the first metal layer 1322 is utilized as the gate of the transistor, and is deposited on insulating substrate 1312. The dielectric 1320 having multiple thicknesses is formed on top of the first metal layer 1312. At least one thicknesses of thin dielectric is deposited in the active regions of the transistors, the active area being defined as the regions consisting at least a portion of the source, at least a portion of the drain, and the space between the source and drain. The field regions have at least a second thickness of dielectric material 1320.

Still referring to FIG. 13, the second layer metal is now deposited, forming the source 1318 and the drain 1316. The troughs between the field dielectrics can be used to guide the ink on one edge of the source/drain definition. The space between the source and drain can be provided by a subtractive method such as laser ablation, etching, or surface energy modification, or by additive methods such as gravure, flexography or contact printing. The semiconductor 1324 is deposited on top of the second layer metal, the semiconductor ink guides by the troughs between the field dielectric.

It has been shown that the varying dielectric thickness can be used to make transistors with various thresholds. The use of a thicker dielectric to isolate transistors described above is a special case thereof. If a metal interconnect runs between two transistors (for example, a source of a first transistor and a drain of second transistor), a parasitic transistor can be created wherein the interconnect acts as a gate, the source is the source of the first transistor, and the drain is the drain of the second transistor. When applying a voltage on the interconnect, carriers are generated underneath the “interconnect gate” of the parasitic transistor, which creates a leakage current between the first and second transistors. If the dielectric thickness deposited between the first and second transistor active regions is made sufficiently thick the parasitic transistor will not turn on even when a maximum operating voltage is applied to the interconnect. Thus, the electrical isolation is thereby significantly improved in terms of leakage current.

While the invention has been described in detail in the foregoing description and illustrative embodiment, it will be appreciated by those skilled in the art that many variations may be made without departing from the spirit and scope of the invention. Thus, it may be understood, for example, that the structures above could include self-assembled monolayers (SAMs), corona treatment, or other surface treatments to obtain desired surface energy and contact angles for optimized print characteristics. The metal layers may contain another conductive layer between the source/drain or gate layers and the surface upon which it is printed in order to promote enhanced adhesion, to increase or decrease wetting of the print surface. Metal layers may be treated with gold immersion or thiol processing to reduce oxidation, increase the effective work function of the metal, and promote desired alignment of the semiconductor polymer and crystalline structures. Various curing steps either at each deposition step or at the end of the entire process may also be included.

We claim:

1. A method of forming an organic transistor device structure comprising:
forming an insulating substrate layer;
forming an organic semiconductor layer;
forming source, drain, and gate regions; and
forming a dielectric layer having at least a first thickness and a second thickness.

2. The method of claim 1, wherein a first dielectric thickness is used in a first organic transistor having a first threshold voltage, and a second dielectric thickness is used to minimize leakage current and capacitance between the first organic transistor and an additional transistor in the organic transistor device structure.

3. The method of claim 2, wherein the dielectric layer has at least a third dielectric thickness, thicker than the first thickness and thinner than the second thickness, to form a second organic transistor having a second threshold voltage.

4. The method of claim 1, wherein the layers and regions are combined to form an isolated top gate organic FET structure.

5. The method of claim 1, wherein the layers and regions are combined to form an isolated bottom gate top contact organic FET structure.

6. The method of claim 1, wherein the layers and regions are combined to form an isolated bottom gate bottom contact organic FET structure.

7. The method of claim 1, wherein the dielectric layer is formed using gravure printing wherein cells on the gravure roll on the image areas are varied in depth.

8. The method of claim 1, wherein the dielectric layer is formed using gravure printing wherein the cells on the gravure roll on the image areas are joined with a lower surface than the surface level of the non-image areas.

9. The method of claim 1, wherein the dielectric layer is formed using gravure printing wherein the cells on the gravure roll on the image area consist of a single cavity.

10. The method of claim 1, wherein the dielectric layer is formed using flexography printing wherein the cells in anolox rolls are varied in depth.

11. The method of claim 1, wherein the dielectric layer is formed using ink jet printing wherein parameters controlling an inkjet head are varied.

12. The method of claim 1, wherein the dielectric layer is formed by printing two successive dielectric layers.

13. The method of claim 1, wherein the dielectric layer is formed using a layer of polyvinylphenol, polypropylene, CYTOP, polyvinylalcohol, ployisobutylene, PMMA, polyethylene terephthalate, poply-p-xylylene, CYMM, or spin-on glass.

14. An organic transistor device structure comprising:
an insulating substrate layer;
an organic semiconductor layer;
source, drain, and gate regions; and
a dielectric layer having at least a first thickness and a second thickness.

15. The device structure of claim 14, wherein a first dielectric thickness is used in a first organic transistor having a first threshold voltage, and a second dielectric thickness is used to minimize leakage current and capacitance.

16. The device structure of claim 15, wherein the dielectric layer has at least a third dielectric thickness, thicker than the first thickness and thinner than the second thickness, to form a second organic transistor having a second threshold voltage.

17. The device structure of claim 14, wherein the layers and regions form an isolated top gate organic FET structure.

18. The device structure of claim 14, wherein the layers and regions form an isolated bottom gate top contact organic FET structure.

19. The device structure of claim 14, wherein the layers and regions form an isolated bottom gate bottom contact organic FET structure.

20. The device structure of claim 14, wherein the dielectric layer comprises two dielectric layers.

21. The device structure of claim 14, wherein the dielectric layer comprises a layer of polyvinylphenol, polypropylene, CYTOP, polyvinylalcohol, ployisobutylene, PMMA, polyethylene terephthalate, poply-p-xylylene, CYMM, or spin-on glass.

22. An organic transistor device structure comprising:
an organic transistor including a dielectric layer having a first thickness; and
an isolation region including a dielectric layer having a second thickness.
